(19) United States
(12) Patent Application Publication
(10) Pub. No.: US 2011/0018550 A1
(43) Pub. Date: Jan. 27, 2011

(54) INTEGRATED CIRCUIT WITH TEST ARRANGEMENT, INTEGRATED CIRCUIT ARRANGEMENT AND TEXT METHOD

(75) Inventors: Franciscus Geradus Maria De Jong, Eindhoven (NL); Alexander Sebastian Biewenga, Eindhoven (NL); A. Van Der Lugt, Waalre (NL); Johannes Arnthonie Josephus Van Geloven, Eindhoven (NL); Pieter Modderkolk, Eindhoven (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/934,697

(22) PCT Filed: Mar. 19, 2009
(86) PCT No.: PCT/IB2009/051157

§ 371 Date: Sep. 27, 2010

(30) Foreign Application Priority Data
Mar. 31, 2008 (EP) 08103186.6

(51) Int. Cl. G01R 31/02

(52) U.S. Cl. 324/537

(57) ABSTRACT

An integrated circuit (100) is disclosed comprising a test arrangement (110, 450) for testing a signal path (150) comprising a capacitive load (152), said test arrangement being arranged to, in a test mode, implement a method in accordance with the present invention by transferring a charge stored in the test arrangement (110, 450) to the capacitive load (152), and by deriving a test result from a voltage formed across the capacitive load (152) by said transferred charge.

The present invention relates to an integrated circuit (IC) comprising a test arrangement for testing a signal path comprising a capacitive load.

The present invention further relates to an IC arrangement comprising at least one of such an IC.

The present invention yet further relates to a method of testing a signal path comprising a capacitive load.

In IC arrangement manufacturing, it is important to ensure that the manufactured arrangement does not comprise any faults in the ICs under test as well as in the connections between the ICs of the IC device. To this end, the ICs as well as the IC arrangement are subjected to a number of tests to verify their correct behavior. In this context, the phrase IC arrangement may also be a multiple IC or multiple die device such as a printed circuit board (PCB), i.e. a printed wiring board (PWB) or system-in-package (SiP). A commonly used test approach is to extend the individual ICs of the IC arrangement with boundary scan test facilities, i.e. facilities compliant with the IEEE 1149.1 standard. Test facilities that are complaint with this standard are sometimes also referred to as being JTAG-compliant. Boundary scan test not only facilitates access to the internal scan chains of the ICs under test, but also has an EXTEST mode in which the interconnections between the ICs of an IC arrangement such as a printed circuit board (PCB) can be tested. A PCB is also known as a printed wiring board (PWB).

Although boundary scan test facilitates versatile testing of ICs and their interconnections, some particular test challenges cannot be solved using boundary scan test. For instance, if an IC is connected to an analog signal path, such a signal path cannot be accurately tested by means of boundary scan testing, because the IEEE 1149.1 standard assumes the communication of digital signals between ICs, which are typically stable over a predefined period such as a clock cycle. Since analog signals typically have time-dependent values, the capture of an accurate signal value cannot be guaranteed using standard boundary scan testing. Moreover, the analog signal path itself may have a time-dependent effect on the analog signal. This problem has been addressed by PCT patent application WO 97/14974, in which a JTAG-compliant arrangement is proposed for accurately testing an analog signal path between two ICs that has a time-dependent effect on the analog signal. To this end, the analog signal path is provided with a test signal comprising a level transition, and an analog-to-digital (A/D) converter is coupled to the other end of the signal path to detect the response of the signal path to the test signal.

In testing IC arrangements, it may be important to be able to detect the location of a fault, such as an open in a connection between two ICs. In case the open is caused by a poor soldering point at the pin of an IC, such a fault can usually be easily detected. However, in case the open appears on a point-to-point connection, a boundary scan test result will only indicate a failure of the connection without providing any insight as to the location of the fault. Insufficient insight into the location of the fault can cause the replacement of a perfectly good IC in the IC arrangement, thus increasing the cost of the IC arrangement manufacturing because a perfectly good IC has been wasted, and the ‘repaired’ IC arrangement still contains the earlier detected fault. This is for instance a problem in the manufacturing of IC assemblies, e.g. PCBs, that comprise a number of ball grid array (BGA) style ICs.

A known technique of detecting open faults in point-to-point signal paths is X-ray analysis. However, X-ray analysis requires the use of expensive machines and does not provide a satisfactory resolution in case of IC arrangements, e.g. PCBs, comprising BGA-style ICs. Moreover, X-ray analysis is time-consuming, which further adds to the cost of the analysis.

PCT patent application WO 99/40448, provides a test arrangement and test method for testing an external signal path of an IC. The test method utilizes the fact that any signal path has reactive components such as a discrete or a parasitic capacitance, or an inductance. To this end, the reactive component is energized through a pin of the IC, and subsequently de-energized through the same pin. The amount of energy released by the reactive component over a period of time is integrated and interpreted as a test result. However, it has been found that this method is not accurate enough to detect the location of open faults in e.g. point-to-point signal paths.

The object of the invention is to provide an IC having a test arrangement that can more accurately locate open faults in a signal path.

Further object of the invention is to provide an IC arrangement including such an IC.

Further object of the invention is to provide a method for more accurately locating open faults in a signal path.

In accordance with a first aspect of the present invention, there is provided an IC comprising a test arrangement for testing a signal path comprising a capacitive load, said test arrangement being arranged to, in a test mode, transfer a charge stored in the test arrangement to the capacitive load, and to derive a test result from a voltage formed across the capacitive load by said transferred charge.

The provision of a test arrangement arranged to store a well-defined amount of charge and subsequently at least partially transfer this charge to the capacitive load, and determining the capacitive load voltage following this charge transfer improves the accuracy of the determination of the capacitive load, and thereby improves the accuracy of the determination of the location of an open fault in case the determined capacitive load voltage deviates from a voltage indicative of a fault-free signal path, because the location of an open will influence the total capacity of the capacitive load of the signal path. The signal path may be a signal path external to the IC, in which case the test arrangement is arranged to access the signal path through a connection member, e.g. a pin or bond pad, of the IC.

In an embodiment, the test arrangement comprises a capacitor having a first region, e.g. a first plate, a further region, e.g. a further plate of opposite polarity to the first plate, and a dielectric material isolating the first region from the further region, a switch coupled between the first region and the signal path, and a controller for controlling the switch, said controller comprising: a variable voltage source for providing the first region with a predefined voltage; and a further voltage source coupled to the further region. This has the advantage that the capacitor can be isolated from the capacitive load during charging of the capacitor by the variable voltage source, e.g. a voltage driver, after which the charge stored in the capacitor may be shared between the capacitor and the capacitive load by closing the switch.

Preferably, the further voltage source is a further variable voltage source for providing the further region with a further predefined voltage. This has the advantage that after closing the switch the further variable voltage source, e.g. a further voltage driver, can pump a predefined amount of charge from the capacitor to the capacitive load. This improves the accuracy of the test, because the amount of charge transferred from the capacitor to the capacitive load is more accurately defined.

In an embodiment, the controller comprises a counter for counting the number of increments, and a comparator for comparing the capacitive load voltage with a reference voltage. This allows for transferring the charge from the test arrangement to the capacitive load a number of times, with a termination of the test occurring as soon as the voltage across the capacitive load has reached the predefined reference voltage, with the number of increments indicating the amount of charge transferred from the capacitor to the capacitive load, thereby providing an accurate estimate of the capacitance of the capacitive load. The test may also terminate when the counter reaches a predefined value indicating that the capacitive load is larger than a predefined amount. This for instance may be useful if the signal path comprising the capacitive load comprises a short, causing the transferred charge to leak away from the capacitive load.

The controller may be responsive to a first data register, and may be arranged to provide the test result to a further data register. These data registers may form a part of a JTAG compliant test access port, and may be coupled between a test data input and a test data output of a JTAG compliant test access port (TAP), the first data register and the second data register being selectable in response to a dedicated instruction being loaded into the instruction register of the test access port. This has the advantage that the capacitive load can be tested in a JTAG compliant manner using dedicated instructions for selecting the capacitive load test mode.

In an embodiment, the controller is arranged to provide the further data register with a test result comprising a counter value, a bit indicating the incremental charge capacitive load voltage matching the reference voltage and a further bit indicating the counter value exceeding a predefined value. Not only does this test result allow an accurate determination of the number of charging cycles from which the capacitance of the capacitive load can be calculated, but it further indicates whether or not the voltage across the capacitive load has reached the reference voltage, and if the counter has reached a predefined value, e.g. its initial value indicating an overflow of an n-bit counter (counting to 2ⁿ−1) in case of 2ⁿ charging cycles having taken place.

The controller may be arranged to control the testing of a plurality of signal paths comprising capacitive loads, e.g. a plurality of external signal paths connected to respective connection members of the IC. To this end, the test arrangement may comprise a routing network such as a network of multiplexers for routing the control signals to the appropriate switches.

Alternatively, the each signal path to be tested may comprise its own controller, e.g. each connection member of the IC may comprise its own controller, with the respective controllers being responsive to respective register cells of the first data register. This has the advantage that more than a plurality of signal paths can be tested in parallel, thus saving test time. To this end, each controller is arranged to write the test result to a respective part of the further data register.

In accordance with a further aspect of the present invention, there is provided an IC arrangement comprising a first integrated circuit having a first plurality of connection members, a second integrated circuit having a second plurality of connection members, and a path comprising a capacitive load, said path connecting a connection member of the first integrated circuit to a connection member of the second integrated circuit, wherein at least one of the first integrated circuit and the second integrated circuit is an integrated circuit according to the present invention. A fault on the signal path of such an IC arrangement can be accurately located using an IC of the present invention.

In accordance with a yet further aspect of the present invention, there is provided a method of testing a signal path comprising a capacitive load, the method comprising: transferring a charge to the capacitive load and determining a voltage formed across the capacitive load formed by said transferred charge. This facilitates accurate location of a fault on the signal path. These steps may be repeated a number of times, and the voltage developing over the capacitive load may be compared with a reference voltage to determine the capacitance of the capacitive load based on the number of charging cycles required to reach the reference voltage.

Advantageously, a charging step comprises disconnecting a capacitor of an IC from the signal path by opening a switch between the capacitor and the signal path; charging the capacitor; closing the switch; and at least partially transferring the charge from the capacitor to the capacitive load of the signal path. Preferably, the full charge of the capacitor is transferred to the capacitive load. This further improves the accuracy of the signal path test.

Embodiments of the invention are described in more detail and by way of non-limiting examples with reference to the accompanying drawings, wherein

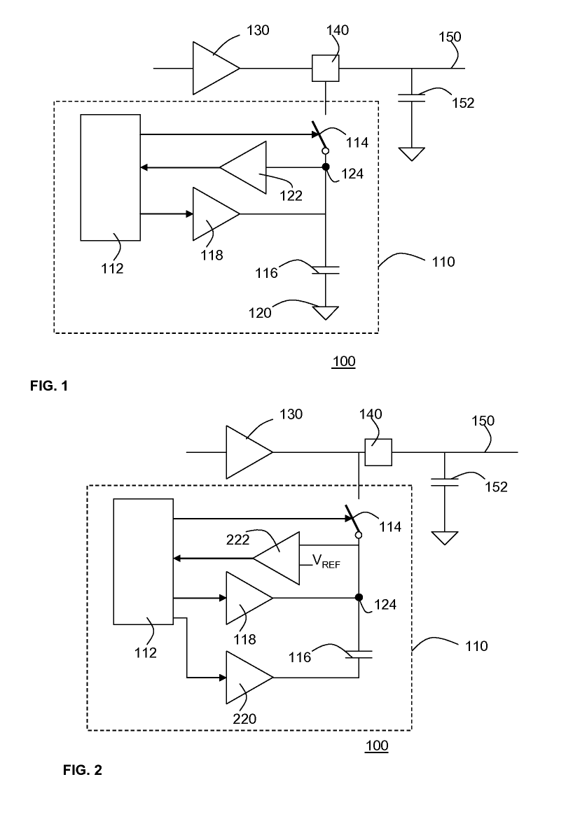

FIG. 1 schematically depicts an aspect of an IC according to an embodiment of the present invention;

FIG. 2 schematically depicts an aspect of an IC according to another embodiment of the present invention;

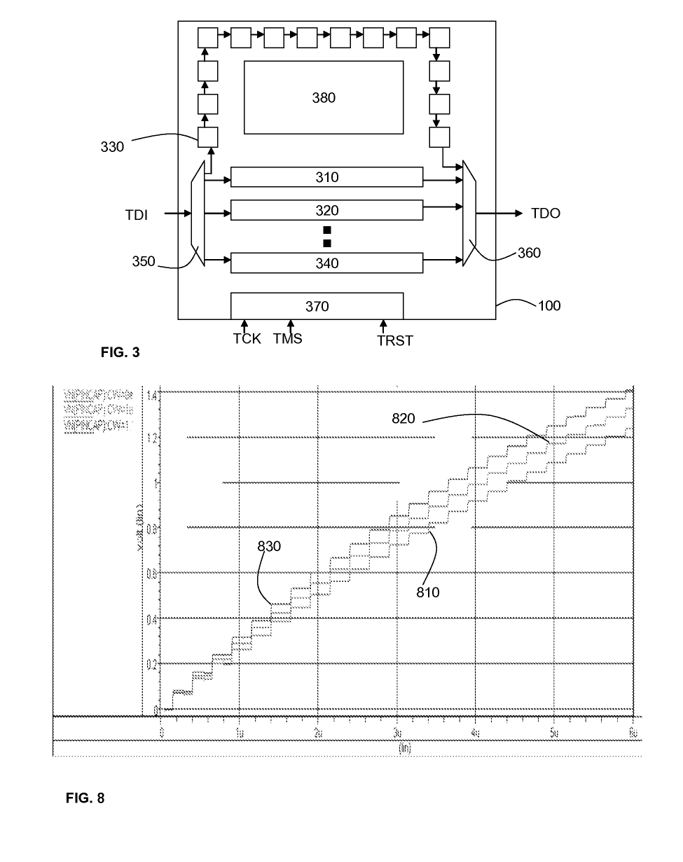

FIG. 3 schematically depicts an aspect of a JTAG-compliant TAP according to an embodiment of the present invention;

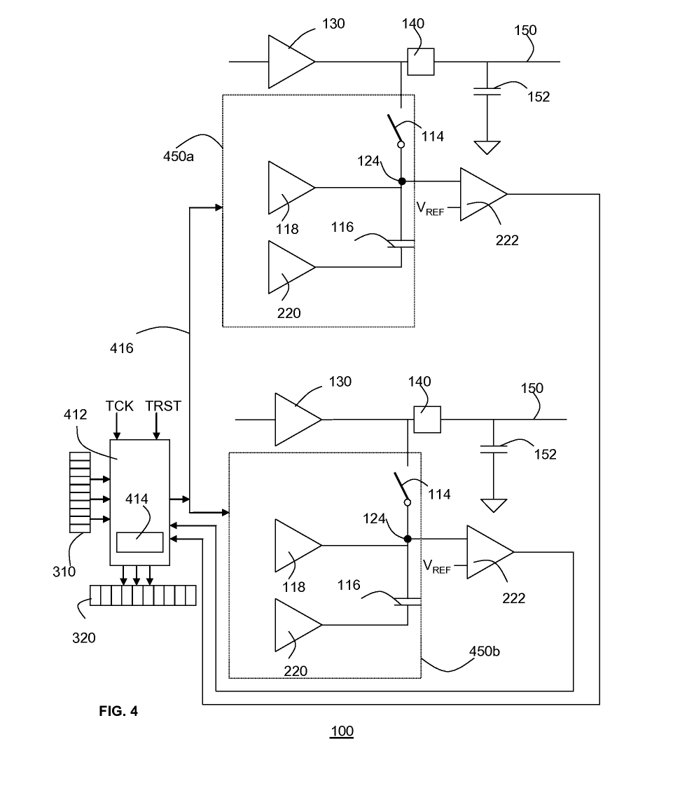

FIG. 4 schematically depicts an aspect of an IC according to yet another embodiment of the present invention;

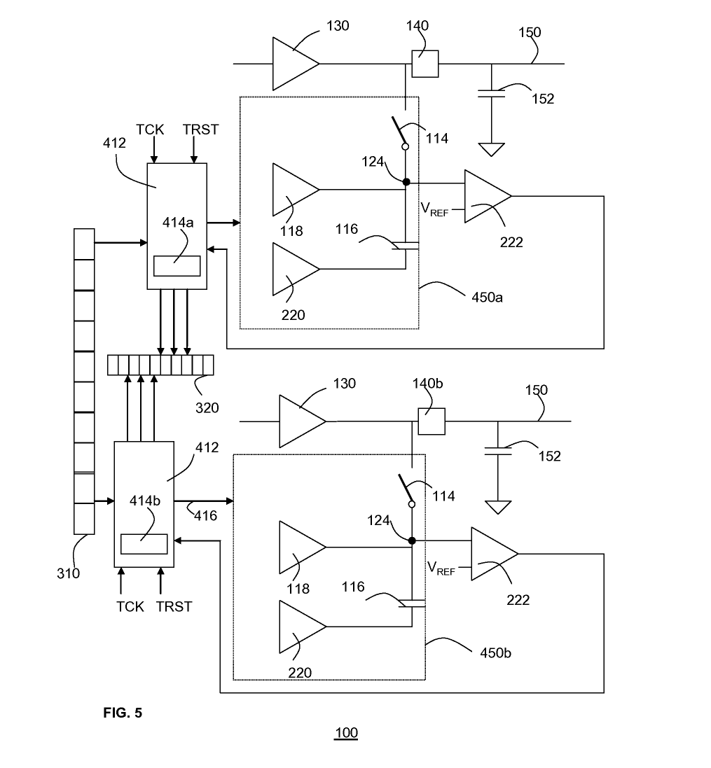

FIG. 5 schematically depicts an aspect of an IC according to yet another embodiment of the present invention;

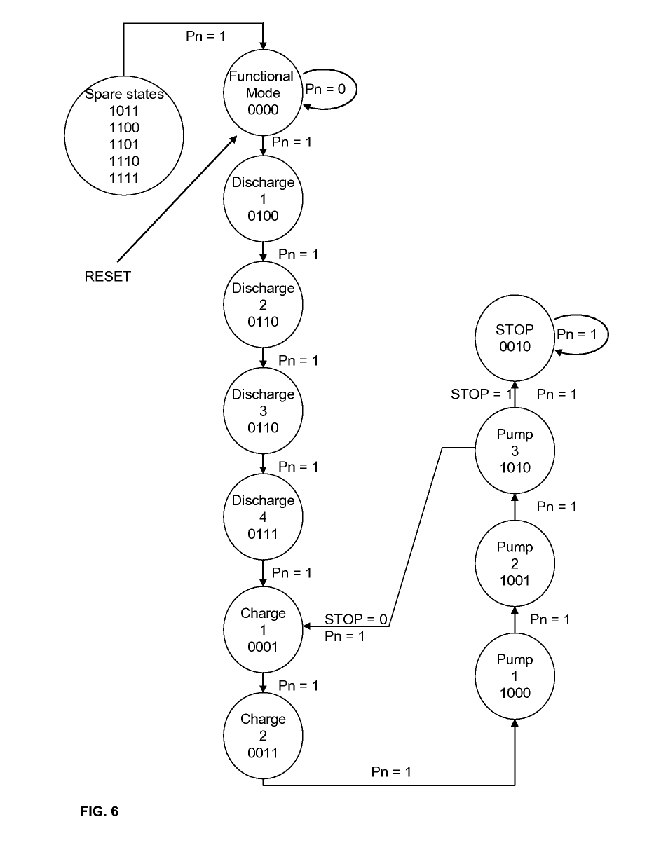

FIG. 6 schematically depicts a state machine of a test arrangement controller in accordance with an embodiment of the present invention;

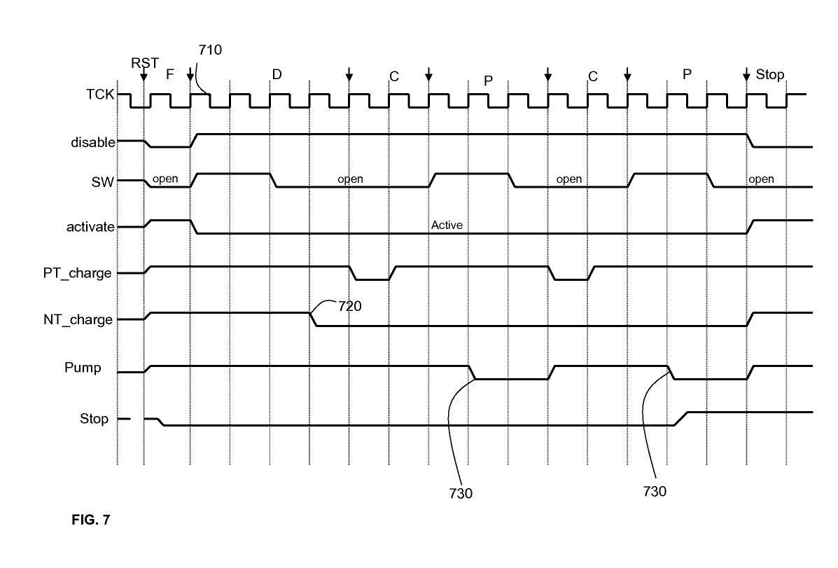

FIG. 7 schematically depicts a timing diagram of the control signals generated by the controller during a signal path test in accordance with an embodiment of the present invention; and

FIG. 8 schematically depicts test results of a number of capacitive loads tested in accordance with an embodiment of the present invention.

It should be understood that the Figures are merely schematic and are not drawn to scale. It should also be understood that the same reference numerals are used throughout the Figures to indicate the same or similar parts.

FIG. 1 depicts a first embodiment of an IC 100 comprising a test arrangement 110 for testing a signal path 150 connected to a connection member 140 such as a bond pad or I/O pin of the IC 100. The connection member 140, e.g. a bond pad 140 or a pin 140 may be driven through a buffer 130, which may be a part of a boundary scan cell (not shown). In the remainder of this description, the connection member 140 may sometimes be referred to as a bond pad or a pin by way of non-limiting example only; the use of these terms is not intended to limit the connection member 140 to a specific type of connection, and is intended to also include other suitable types of connection members 140.

The signal path 150 has a capacitive load, which is modeled by capacitor 152 in FIG. 1. The total capacitive load of the signal path 150 typically includes the sum of the capacitances of the buffer 130, connection member 140, e.g. a bond pad 140 or a pin 140, and the conductive track forming the external connection to the bond pad 140, such as a metal track of a PWB. Such a track may for instance interconnect respective bond pads of two or more ICs of an IC arrangement formed by a number of ICs mounted on the PWB. The capacitive load 152 may also include other capacitances such as the IC package load.

The test arrangement 110 comprises a controller 112, a voltage driver 118, e.g. a buffer, and a capacitor 116 coupled to the signal path 150 via a switch 114. The opposite polarity of the capacitor 116 is coupled to a fixed voltage source, e.g. ground. The switch may be any device suitable for switching between a connected and a disconnected state, e.g. a transistor. The test arrangement 110 further comprises an analog-to-digital converter (ADC) 122. The test arrangement 110 is arranged to implement an embodiment of the method of the present invention.

In a first step, the switch 114 is closed, i.e. placed in a conductive state, by the controller 112, and a low voltage is driven through the voltage driver 118 to discharge the capacitor 116 and the capacitive load 152. Subsequently, the switch 114 is opened, i.e. placed in a non-conductive state, by the controller 112, after which the controller charges the capacitor 116 by driving a high voltage through the voltage driver 118. The amount of charge stored in the capacitor 116 is well-defined because the capacitance of the capacitor 116 and the voltage across the capacitor 116, i.e. the voltages provided by the voltage driver 118 and voltage source 120 are well-defined. Next, the switch 114 is closed by the controller 112, such that the charge stored in the capacitor 116 is shared between the capacitor 116 and the capacitive load 152.

The voltage established on the node 124 by this charge sharing, i.e. the partial charge transfer from the capacitor 116 to the capacitive load 152, scales with the total capacitance of the capacitive load 152. When a voltage Vᵢ is used to store a charge Q on a capacitor Cᵢ having a known capacitance (capacity) such as capacitor 116, this voltage is defined by Vᵢ=Q/Cᵢ. When this charge Q is shared between the capacitor Cᵢ and a further capacitive load C_{L}, having an unknown capacitance, a node between Cᵢ and C_{L} will exhibit a voltage V_{f} defined by V_{f}=Q/(Cᵢ+C_{L}) after sharing the initial charge. By measuring V_{f}, C_{L} can be determined.

Therefore, by determining the voltage on the node 124, e.g. by means of the ADC 122, the size of the capacitive load 152 can be determined. For instance, a relatively small capacitive load 152 may be indicative of an open in the vicinity of the connection member 140, whereas a large capacitive load 152 may be indicative of the signal path 150 comprising a large conductive connection, e.g. a metal track of a PWB.

The charge sharing principle shown in FIG. 1 is attractive because it requires relatively little IC area overhead. However, it may require a relatively large capacitor 116, and the test result may have a limited resolution. To this end, an alternative test arrangement 110 may also be used. This alternative test arrangement 110 is shown in FIG. 2, in which the fixed voltage source 120 is replaced by a further voltage driver 220, e.g. a further buffer, under control of the controller 112. Moreover, the ADC 122 is replaced by a comparator 222 having a first input connected to the node 124 and a second input connected to a reference voltage. This test arrangement is arranged to implement an alternative embodiment of the method of the present invention.

In a first step, the switch 114 is closed, i.e. placed in a conductive state, by the controller 112, and a low voltage is driven through the voltage driver 118 and the further voltage driver 220 to discharge the capacitor 116 and the capacitive load 152. Subsequently, the switch 114 is opened, i.e. placed in a non-conductive state, by the controller 112, after which the controller charges the capacitor 116 by driving a high voltage through the voltage driver 118. The amount of charge stored in the capacitor 116 is well-defined because the capacitance of the capacitor 116 and the voltage across the capacitor 116, i.e. the voltages provided by the voltage driver 118 and voltage source 120 are well-defined, as previously explained. Next, the switch 114 is closed by the controller 112, and the further voltage driver 220 is driven to a high voltage, such that the charge stored in the capacitor 116 is effectively transferred to the capacitive load 152. Hence, the voltage V_{f} on the node 124 may now be expressed as V_{f}=Q/C_{L}, because no charge is left on the capacitor 116. These steps are repeated until the voltage on the node 124 has matched the reference voltage. After each step, the voltage change on the node 124 may be expressed as follows: ΔV=Cᵢ*(Vᵢ−V_{L})/(Cᵢ+C_{L}), or V_{node}_{_{—}}_{new}=(Vᵢ*Cᵢ+V_{node}_{_{—}}_{old}*C_{L})/(Cᵢ+C_{L}), wherein V_{node}_{_{—}}_{old} and V_{node}_{_{—}}_{new} are the respective voltages on the node 124 before and after the additional charging and pumping step.

The size of the capacitive load 152 may be determined from the amount of charge transferred from the capacitor 116 to the capacitive load 152 times the number of charge/discharge cycles required to reach the reference voltage. To this end, the controller 112 is arranged to count the number of times that a charge is transferred from the capacitor 116 to the capacitive load 152. The controller 112 may be arranged to output this count as a test result. This test result can have a high accuracy, especially when the capacitance of the capacitor 116 is kept relatively small, because this causes the total amount of charge transferred to the capacitive load 152 to be increased in small increments. It will be understood that the accuracy of this test method can be further improved by ensuring that the frequency of charge transfer steps is substantially higher than the rate of current leakage from the capacitive load 152, such that the test result is not obscured by loss of charge from the capacitive load 152.

At this point, it is emphasized that although the test arrangement 110 has been described in the context of testing external signal paths, it is to be understood that the test arrangement may be used for testing any signal path, e.g. signal paths internal to the IC, that are connected to the test arrangement 110 via a switch 114. Moreover, it is emphasized that the ADC 122 in FIG. 1 and the comparator 222 in FIG. 2 are shown by way of non-limiting example only. Not only may the test arrangement 110 of FIG. 2 use an ADC 122 instead of a comparator 222, and vice versa, but it should be understood that other suitable voltage determining devices may also be used. The test arrangement of FIG. 1 may also use a plurality of charge sharing steps to determine the capacitive load 152.

In FIG. 1, one of the terminals of the switch 114 is connected to the bond pad 140, whereas in FIG. 2, the same terminal of the switch 114 is connected to the conductive path between the connection member 140 and the buffer 130. Both implementations are equally feasible.

The controller 112 may be accessed in any suitable way, e.g. via dedicated pins of the IC 100. However, in a preferred embodiment, the test controller 112 can be accessed in a JTAG-compliant manner. As shown in FIG. 3, the IC 100 may include a JTAG-compliant TAP extended to include a first data register 310 for receiving signal path test configuration information, and a further data register 320 for receiving signal path test results in addition the mandatory data registers such as the boundary scan register 330 which provided an interface between the I/O bond pads of the IC 100 and its internal logic 380, an instruction register 340 arranged to select the data register to be connected in between test data input TDI and test data output TDO by providing MUX 350 and MUX 360 with configuration signals, and a TAP controller 370 for controlling the TAP. The details of the TAP controller 370 are well-known to the skilled practitioner, and are not further discussed for reasons of brevity only.

The first data register 310 may be selected by a first dedicated instruction for configuring a signal path test, after which the signal path configuration data may be loaded into the first data register 310. The controller 112 shown in FIG. 1 and FIG. 2 is responsive to the configuration data in the first data register 310. Subsequently, a dedicated instruction for starting the signal path test is shifted into the instruction register 340. This instruction selects the further test data register 320. The signal path test is started when the TAP controller 370 exits the UPDATE-INSTRUCTION-REGISTER state. The controller 112 is arranged to write its test results to the further test data register 320. For instance, the controller 112 may be arranged to write a measured voltage into the further test data register 320. As previously explained, this may be a digital representation of a voltage measured by an ADC, or another suitable representation of the measured voltage.

Alternatively, the controller may be arranged to write the following bit string into the further test data register 320: <counter bits 0-n><reference voltage indication bit><counter overflow bit>. For instance, in the case of a 6-bit counter value, the total length of this bit string is 8 bits. The reference voltage indication bit indicates whether or not the voltage measured on the node 124 has matched the reference voltage. The counter overflow bit indicates whether the number of charging cycles has exceeded the resolution of the counter, e.g. more than 63 charging cycles in the case of a 6-bit counter. This information can be used to accurately characterize the capacitive load 152 of the signal path 150. The test result data stored in the further data register 320 may be shifted out through TDO following every charge transfer cycle of the signal path test. Alternatively, the test results may be shifted out following the completion of the signal path test, e.g. by keeping the TAP controller in a RUN-TEST-IDLE state during the signal path test.

The JTAG-compliant control of the controller 112 allows for the testing of multiple signal paths, either sequentially or in parallel. FIG. 4 shows an embodiment of an IC 100 for testing a plurality of signal paths 150 in a sequential fashion. The IC 100 comprises a single controller 412 having a counter 414 for counting the number of charge transfer steps from a capacitor 116 to a capacitive load 152, with each signal path 150 being associated with a respective test arrangement 450a, 450b, each of said test arrangements comprising a switch 114, a capacitor 116, a first voltage source 118 controlled by the controller 412 and further voltage source, which may be a fixed voltage source or a further voltage source 220 controlled by controller 412, and a voltage determining source for determining the voltage on node 124, such as a comparator 222 further coupled to a reference voltage, as previously explained. In other words, the test arrangements 450a and 450b may implement a test arrangement as depicted in FIG. 1 or FIG. 2 and/or described in the detailed description of these FIGS. The respective voltage determining sources are arranged to return a test result to the controller 412, which is arranged to write the test result in the further data register 320 for shifting out via TDO. The outputs of the respective comparators 222 may be coupled to the controller 112 in any suitable manner, such as individually coupled to the controller 112 or coupled to the controller via a shared conductor, e.g. a bus arrangement.

The respective test arrangements 450a, 450b may be selected using the configuration information uploaded into the first data register 310. This configuration information may be used to configure a selection network (not shown) between the controller 412 and the respective test arrangements 450a, 450b. The configurable selection network may be implemented in any suitable way, e.g. by means of a tree of multiplexers, or any other configurable fan-out structure. It will be appreciated that FIG. 4 depicts two test arrangements 450a, 450b by way of non-limiting example only. Larger numbers of test arrangements, e.g. a test arrangement for each bond pad of the IC 100, are equally feasible.

It should further be understood that the control line 416 between the controller 412 and the respective test arrangements 450a, 450b is shown as a single line for reasons of clarity only, and that the controller is arranged to provide each test arrangement 450a, 450b with a plurality of control signals, as will be explained in more detail later. The controller 412 may be controlled using the JTAG test clock signal TCK, and may be responsive to the JTAG test reset signal TRST for resetting the controller 412 and its counter 414. In case the frequency of the charging cycles is controlled by the TCK frequency, care must be taken that the TCK frequency is sufficiently high to avoid charge leaking from the capacitive load 152 under investigation, as previously explained.

In an alternative (not shown) to the arrangement shown in FIG. 4, the controller 412 may also comprises the capacitor 116, the first voltage source 118 and the further voltage source 220, with these elements being omitted from the respective test arrangements 450a, 450b. This provides a centralized test arrangement for each signal path 150, with each signal path 150 being coupled to the single capacitor 116 via a respective switch 114. This, however, is not a preferred solution because of the added capacitance of the relatively long conductive paths required between the centralized capacitor 116 and the respective switches 114, which may deteriorate the accuracy of the determination of the capacitive load 152.

FIG. 5 shows an IC 100 for simultaneously testing a plurality of signal paths 150, with each signal path having a dedicated test arrangement 450a, 450b, each controlled by a dedicated controller 412. Each controller 412 is responsive to a respective configuration bit in the first data register 310. Hence, the data register 310 is arranged to select which controllers 412 are to be involved in the signal path test. The respective counters 414a, 414b of the controllers 412 are arranged to count the number of charge transfers between the respective capacitors 116 and the respective capacitive loads 152. Each controller 412 is arranged to write a test result into a respective part of the further data register 320, such as the previously mentioned bit string <counter bits 0-n><reference voltage indication bit><counter overflow bit>. It is reiterated that each controller 412 is arranged to provide a plurality of control signals over a plurality of conductors to its test arrangement 450.

It should be understood that not all controllers 412 have to be controlled through the JTAG-compliant TAP. For instance, the IC 100 may comprise one or more test arrangements 450 that are controlled directly via dedicated pins of the IC 100 by means of external controllers 412. Moreover, not every controller 412 has to produce the same number of test result bits. For instance, some signal paths 150 may have a much larger capacitive load 152 than other signal paths 150, in which case the controller 412 may have a larger counter 414.

The controller 412 is typically arranged to generate the following set of control signals for the test arrangement: (SW, PT_charge, NT_Charge, Push). SW controls the switch 114. A low SW signal indicates the switch being in a non-conductive mode. The signals PT_charge and NT_charge control the first voltage source 118, and indicate a positive voltage and a negative voltage being driven to the capacitor 116 respectively. The signal Push controls the second voltage source 220 and indicates a high voltage driven to the capacitor 116 for transferring the charge stored on the capacitor 116 to the capacitive load 152.

The controller 112 or 412 is typically configured to ensure that the test arrangement of the present invention is controlled in accordance with the method of the present invention. The skilled person will understand that the controller 112 or 412 may be implemented in any suitable way. In an embodiment, the controller 112 or 412 may comprise a state machine for generating the respective control signals for its test arrangement 450. An example embodiment of such a state machine is shown in FIG. 6, and will be explained with the aid of FIG. 7. It should be understood that this is an example embodiment of such a state machine and that alternative embodiments, for instance in which the number of states are varied, are equally feasible.

The controller 112 or 412 may be reset in a number of suitable ways, such as by the JTAG test reset signal TRST, by the Test-Logic-Reset state of the JTAG TAP controller 370, or by the corresponding configuration bit (Pn) in the first data register 310 assuming a predefined logic value, e.g. Pn=0. In the “Functional Mode” state, which is state F in FIG. 7, the outputs of the controller 112 or 412 are set to default values. The disable signal for buffer 130 is low, which means that the buffer 130 is controlled by functional logic (not shown).

The switch control signal SW is low; this means that the switch 114 is open, i.e. disconnected from the signal path 150, such that the test arrangement 110 does not interfere with the signal path 150. The Activate signal which controls the comparator 222 is high. This means the comparator 222 is inactive. The PT_charge signal is high and NT_charge signal is high; this means that voltage source 118 drives a low voltage on its output, as is also demonstrated in Table I.

TABLE I
Voltage source 118 control signals

| PT_Charge | NT_Charge | Voltage source 118 |
|---|---|---|
| 0 | 0 | 1 |
| 0 | 1 | Forbidden |
| 1 | 0 | Tri-state |
| 1 | 1 | 0 |

The Pump signal is high; this means that the voltage source 220 also drives a low voltage on its output.

The controller (112) is brought in the signal path test mode if the corresponding bit Pn in the first data register 310 assumes a further predefined logic value, e.g. Pn=1. This initiates the test of signal path 150. During this test, the further data register 320 is selected for receiving test results.

In FIG. 6, the controller changes state at every positive edge of a test clock. This test clock may be the JTAG clock TCK or any other suitable periodic signal source, e.g. an internal clock generator. In FIG. 6, the controller is responsive to TCK.

After being enabled, the controller steps from the “Functional Mode” state to “Discharge 1” state. This is the first clock cycle of period D in FIG. 7 at the next (positive) edge of the clock. In the “Discharge 1” state the following actions take place; buffer 130 is disabled, comparator 222 is activated, and switch 114 is closed. This discharges node 124 including the capacitor 116 and the capacitive load 152 because the voltage sources 118 and 220 still drive a low voltage.

At the next positive clock edge, the controller 412 transitions to the “Discharge 2” state indicated by the second clock cycle 710 of period D in FIG. 7. The “Discharge 2” state is a continuation of the “Discharge 1” state. This is to ensure that the node 124 is kept in the discharge state long enough to become fully discharged. In FIG. 6, a single “Discharge 2” state is shown. However, it will be appreciated that the controller 112 or 412 may be kept in this state for any appropriate number of clock cycles to ensure that the node 124 and associated capacitances are fully discharged. The number of clock cycles 710 during which the controller 112 or 412 is kept in the “Discharge 2” state will depend on the size of the total capacitance to be discharged and the clock frequency.

At the next (positive) clock edge the controller 112 or 412 transitions to the “Discharge 3” state. This is the third clock cycle 710 of period D in FIG. 7. In this state, the SW signal that controls switch 114 goes low and the switch 114 is opened, i.e. disconnected from the signal path 150.

At the next (positive) clock edge, the controller 112 or 412 transitions to the “Discharge 4” state indicated by the fourth clock cycle of D in FIG. 7. In this state, the NT_charge signal goes low, causing the output of voltage source 118 to become tri-stated.

At the next (positive) clock edge, the controller 112 or 412 transitions to the “Charge 1” state, as indicated by the first clock cycle 710 of period C in FIG. 7. In this state, the PT_charge signal goes low and the output of voltage source 118 is driven high, thus charging capacitor 116.

At the next (positive) clock edge, the controller 112 or 412 transitions to the “Charge 2” state, as indicated by the second clock cycle of period C in FIG. 7. In this state, the PT_charge signal goes high and the output of voltage source 118 is tri-stated, thereby maintaining the charge stored on of capacitor 116.

At the next (positive) clock edge, the controller 112 or 412 transitions to the “Pump 1” state, indicated by the first clock cycle of P in FIG. 7. In this state, the SW signal goes high, causing the switch 114 to close, and causing the initiation of the charge transfer from capacitor 116 to the capacitive load 152.

At the next (positive) clock edge, the controller transitions to the “Pump 2” state indicated by the second clock cycle 710 of period P in FIG. 7. The Pump signal goes low, causing the output of voltage source 220 to be driven high. This effectively pumps the charge of capacitor 116 onto the capacitive load 152.

At the next (positive) clock edge the controller 112 or 412 transitions to the “Pump 3” state indicated by the third clock cycle 710 of period P in FIG. 7. In this state, the SW signal goes low and the switch 114 is opened.

If, in the “Pump 2” state, the reference voltage Vref of the comparator 222 has been exceeded by the voltage level at node 124, the output of the comparator 222, i.e. the Stop signal goes high. If this reference voltage has not been exceeded, the Stop signal will remain low.

The states “Charge 1”, “Charge 2”, “Pump 1”, “Pump 2” and “Pump 3” are repeated until the Stop signal goes high, until the counter 414 indicates an overflow or a reset is received. This is indicated in FIG. 6 by the loopback from state “Pump 3” to state “Charge 1”. If the Stop signal goes high, the “Stop state” is entered and the controller 112 or 412 will remain in this state until a reset is received. In the “Stop state” the outputs of the controller 112 or 412 have the same value as in the “Functional Mode” state.

Hence, the stop signal indicates the end of the signal path test, thus forcing the controller 412 into state STOP. As long as signal STOP=0 and Pn=1 and no reset is received, the controller 112 or 412 will repeat the charging and pumping cycles, as indicated in the state machine in FIG. 6.

Although FIG. 7 has already been briefly explained in the context of FIG. 6, a more detailed explanation will be given below. FIG. 7 gives an overview of the time-dependent signals generated by the controller 412 (or 112) in the various states of the state machine in FIG. 6. In functional mode F, the buffer disable signal is low, indicating that the buffer 130 is enabled. The switch signal SW is low, indicating that switch 114 is open. The comparator activate signal is high, indicating that the comparator 222 is disabled. The signals PT_charge, NT_charge and Pump are all high, indicating that the voltage sources 118 and 220 are kept in a low voltage state, e.g. connected to ground. Upon entering the signal path test mode, the controller 412 deactivates the buffer 130 as indicated by the disable signal going high. This signal remains high for the duration of the test. The comparator 222 is activated for the duration of the test, as indicated by the activate signal going low. The test comprises a discharge cycle D and a number of alternating charge cycles C and pump cycles P. Each of these cycles comprises a number of clock cycles 710, as explained in the context of the state machine in FIG. 6. The clock cycles 710 may be the JTAG test clock TCK cycles, or a periodic signal generated by another periodic signal source, e.g. an internal clock generator.

At the start of the discharge cycle D, signal SW goes high, thus closing switch 114. This connects the capacitive load 152 to the low voltage potential, thus effectively discharging the capacitive load 152. At the end of the discharge cycle, the switch 114 is opened again (SW goes low), and signal NT_charge is switched to low, as indicated by transition 720. This transition coincides with a reset of the counter 414, and disconnects the first voltage source 118 from ground. Alternatively, the counter 414 may be reset by the corresponding bit Pn in the first data register 310 assuming a predefined bit value, e.g. ‘0’, or by a JTAG reset, i.e. the TAP controller 370 assuming the Test-Logic-Reset state.

Next, in charging cycle C, PT_charge is switched to low. This causes the first voltage source 118 to drive a high voltage onto the first terminal of the capacitor 116, thereby storing a charge on capacitor 116. The charging cycle C is followed by a pumping cycle P, in which the switch 114 is closed again, thereby connecting the capacitive load 152 to the charged capacitor 116, after which the Pump signal goes low, thus forcing the further voltage source 220 to drive a voltage onto the opposite terminal of the capacitor 116 such that the charge stored on the capacitor 116 is transferred to the capacitive load 152. This transition 730 of the pump signal triggers an increment of the counter 414. The charge cycles and pump cycles are repeated until the comparator 222 indicates that the voltage on node 124 has reached the reference voltage, as indicated by the signal Stop, or if the test is terminated otherwise, e.g. by a reset signal or by an overflow of the counter 414, as previously explained.

FIG. 8 shows the effect of the size of the capacitor 116 on the number of cycles required to charge the capacitive load 152 to the reference voltage. Trace 810 corresponds to a capacitor 116 having a 90 fF capacitance, trace 820 corresponds to a capacitor 116 having a 100 fF capacitance, and trace 830 corresponds to a capacitor 116 having a 110 fF capacitance. FIG. 8 clearly demonstrates that a higher capacitance of the capacitor 116 causes the node 124 to more quickly reach a reference voltage, e.g. a reference voltage of 1.2 V. The reference voltage may be chosen to be the supply voltage.

For trace 810, the reference voltage was reached in 23 steps, for trace 820, the reference voltage was reached in 21 steps and for trace 830, the reference voltage was reached in 19 steps. The capacitor 116 is preferably kept as small as practically possible in terms of available test time, because this improves the resolution of the signal path test and limits the area overhead of the test arrangement 450.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The invention can be implemented by means of hardware comprising several distinct elements. In the device claim enumerating several means, several of these means can be embodied by one and the same item of hardware. The mere fact that certain measures are recited in mutually different dependent claims does not indicate that a combination of these measures cannot be used to advantage.

1. An integrated circuit comprising:
a test arrangement for testing a signal path comprising a capacitive load, said test arrangement being arranged to, in a test mode, transfer a charge stored in the test arrangement to the capacitive load, and to derive a test result from a voltage formed across the capacitive load by said transferred charge.

2. The integrated circuit as claimed in claim 1, characterized in that the signal path is an external path comprising the capacitive load, and that the external path is connected to the test arrangement via a connection member.

3. The integrated circuit as claimed in claim 1, characterized in that the test arrangement comprises at least one capacitor.

4. The integrated circuit as claimed in claim 3, characterized in that the at least one capacitor has a first region, a further region and a dielectric material isolating the first region from the further region.

5. The integrated circuit as claimed in claim 3, characterized in that the test arrangement comprises at least one variable voltage source for providing the at least one capacitor with a predefined voltage.

6. The integrated circuit as claimed in claim 1, characterized in that test arrangement comprises a further voltage source being coupled to the at least one capacitor.

7. An integrated circuit as claimed in claim 6, characterized in that the further voltage source is a variable voltage source for providing the at least one capacitor with a predefined voltage.

8. The integrated circuit as claimed in claim 1, characterized in that at least one switch is provided being coupled between the test arrangement and the signal path.

9. The integrated circuit as claimed in claim 1, characterized in that the charge is a fixed charge.

10. The integrated circuit as claimed in claim 9, characterized in that the test arrangement is arranged to transfer the fixed charge to the capacitive load in each of a number of transfer steps.

11. The integrated circuit as claimed in claim 10, characterized in that a counter is provided for counting the number of transfer steps.

12. The integrated circuit as claimed in claim 1, characterized in that the test arrangement comprises a comparator for comparing the capacitive load voltage with a reference voltage.

13. The integrated circuit as claimed claim 1, characterized in that the test arrangement comprises at least one controller.

14. The integrated circuit as claimed in claim 5, characterized in that the controller is arranged to control the further voltage source and/or the switch and/or the variable voltage source.

15. The integrated circuit as claimed in claim 13, characterized in that the controller is responsive to a first data register, and arranged to provide the test result to a further data register.

16. The integrated circuit as claimed in claim 15, wherein the first data register and the further data register are comprised in a JTAG compliant test access port, coupled between a test data input (TDI) and a test data output (TDO) of the JTAG compliant test access port, the first data register and the second data register being selectable in response to a dedicated instruction being loaded into the instruction register of the test access port.

17. The integrated circuit as claimed in claim 15, wherein the test result comprises a counter value, a bit indicating the capacitive load voltage matching a reference voltage and a further bit indicating the counter value exceeding a predefined value.

18. The integrated circuit as claimed in claim 1, characterized in that a plurality of connection members are provided, wherein each connection member is arranged to be connected to a respective external signal path comprising a capacitive load, and wherein each connection member is coupled to a respective capacitor having a first region, a further region and a dielectric material isolating the first region from the further region via a switch coupled between the first region and the respective signal path.

19. The integrated circuit as claimed in claim 18, characterized in that a controller comprises a configurable routing network responsive to a first data register for selecting one of said external signal paths for testing.

20. An integrated circuit according to claim 19, wherein each signal path has a separate controller, each controller being responsive to a respective register cell of the first data register, and being arranged to provide a respective portion of the further data register with the test result.

21. An integrated circuit arrangement comprising a first integrated circuit having a first plurality of connection members, a second integrated circuit having a second plurality of connection members, and a path comprising a capacitive load, said path connecting a connection member of the first integrated circuit to a connection member of the second integrated circuit, wherein at least one of the first integrated circuit and the second integrated circuit is an integrated circuit according to claim 1.

22. A method of testing a signal path comprising a capacitive load, the method comprising:
transferring a charge to the capacitive load; and
determining a voltage formed across the capacitive load formed by said transferred charge.

23. The method as claimed in claim 22, wherein the signal path is accessible by an integrated circuit comprising a capacitor coupled to the signal path via a switch, and wherein the transferring step comprises:
disconnecting the capacitor from the signal path by opening the switch;
charging the capacitor;
closing the switch; and
at least partially transferring the charge from the capacitor to the capacitive load of the signal path.

24. The method as claimed in claim 13, wherein the step of determining the voltage comprises comparing the capacitive load voltage with a reference voltage.
